(19) United States
(12) Patent Application Publication
(10) Pub. No.: US 2026/0009158 A1
(43) Pub. Date: Jan. 8, 2026

(54) AIN SINGLE CRYSTAL SUBSTRATE AND DEVICE

(71) Applicant: NGK INSULATORS, LTD., Nagoya-shi (JP)

(72) Inventors: Hiroharu KOBAYASHI, Kasugai-shi (JP); Kyohei ATSUJI, Nagoya-shi (JP); Katsuyuki TAKEUCHI, Aisai-shi (JP); Eri KAWAGUCHI, Nagoya-shi (JP)

(21) Appl. No.: 19/328,333

(22) Filed: Sep. 15, 2025

Related U.S. Application Data
(63) Continuation of application No. PCT/JP2023/010474, filed on Mar. 16, 2023.

(51) Int. Cl. C30B 29/40; C30B 23/06; C30B 35/00

(52) U.S. Cl. CPC C30B 29/403; C30B 23/066; C30B 35/002; C30B 35/007

(57) ABSTRACT

There is provided an AlN single-crystal substrate having a two-layer structure composed of an AlN single crystal as a whole, which is distinguishable into a first layer and a second layer in a thickness direction based on an impurity concentration. The AlN single-crystal substrate includes boron as an impurity, and a boron atom concentration in the first layer is 9.4×10¹⁸ cm⁻³ or more, and is at least 10 times a boron atom concentration in the second layer.

### CROSS-REFERENCE TO RELATED APPLICATION

This application is a continuation application of PCT/JP2023/010474 filed Mar. 16, 2023, the entire contents of which are incorporated herein by reference.

### BACKGROUND OF THE INVENTION

### 1. Field of the Invention

The present invention relates to an AlN single-crystal substrate and a device comprising the AlN single-crystal substrate.

### 2. Description of the Related Art

Aluminum nitride (AlN) single crystals have recently attracted attention as base substrates for deep ultraviolet light emitting elements using AlN-based semiconductors. For example, AlN, AlGaN, and the like are used as AlN-based semiconductors. These AlN-based semiconductors have a direct band gap structure, which makes them suitable for light-emitting devices and applicable to light emitting diodes (LEDs) and laser diodes (LDs) in the deep ultraviolet region usable for applications such as disinfection.

In such light-emitting devices, to achieve high transmittance in the ultraviolet region, it is desirable that the impurity concentration in the base substrate is low. Patent Literature 1 (JP6080148B) discloses an AlN single crystal comprising an oxygen atom and a carbon atom, wherein the oxygen atom concentration is 5×10¹⁷ cm⁻³ or more and 5×10¹⁸ cm⁻³ or less, and the carbon atom concentration is 4×10¹⁷ cm⁻³ or more and 4×10¹⁸ cm⁻³ or less, and thus, has an oxygen atom concentration higher than the carbon atom concentration. This literature discloses that in order to reduce the impurity content, advanced control or a special apparatus is required during single-crystal growth; however, the above-described single crystal in which the oxygen atom and carbon atom concentrations have been controlled has good transparency to ultraviolet light. Patent Literature 2 (JP2009-78971A) discloses an AlN single-crystal substrate having an AlN composition, a total impurity density of 1×10¹⁷ cm⁻³ or less, and an absorption coefficient of 50 cm 1 or less in a total wavelength range of 350 to 780 nm.

Additionally, regarding impurities in an AlN single crystal, Patent Literature 3 (JP4811082B) discloses an n-type AlN crystal having a structure in which a portion of Al atoms in the AlN crystal have been replaced by a group IIIa element and/or a group IIIb element, and one of adjacent N atoms has been simultaneously replaced by an O atom, wherein the group IIIa element and/or the group IIIb element is one or more elements selected from the group consisting of Y, Sc, La, Ce, and Ga. This literature describes the relationship between the oxygen concentration and the total concentration of the group IIIa element and/or the group IIIb element. Patent Literature 4 (JP6932995B) discloses an AlN single crystal having a wurtzite-type crystal structure and having a boron content of 0.5 ppm by mass or more and 251 ppm by mass or less.

### CITATION LIST

### Patent Literature

Patent Literature 1: JP6080148B
Patent Literature 2: JP2009-78971A
Patent Literature 3: JP4811082B
Patent Literature 4: JP6932995B

### SUMMARY OF THE INVENTION

As described above, a possible solution to control the properties of an AlN single crystal, such as achieving high deep-ultraviolet transmittance and n-type conduction, may be to control the relationship of impurity contents in the AlN single crystal. However, the AlN single-crystal substrates, as disclosed in Patent Literatures 1 to 4, are susceptible to chipping (defects including chips and cracks) when processed (such as ground, polished, or cut), leaving room for improvement in terms of yield. Therefore, it is desirable to reduce chipping of AlN single-crystal substrates during processing of the AlN the single-crystal substrates.

The present inventors have found that an AlN single-crystal substrate having a two-layer structure composed of an AlN single crystal as a whole with a controlled concentration of boron atoms as impurities, is less susceptible to chipping when processed (such as ground, polished, or cut).

Therefore, it is an object of the present invention to provide an AlN single-crystal substrate that is less likely to have chipping when processed (such as ground, polished, or cut).

The present invention provides the following aspects:

### Aspect 1

An AlN single-crystal substrate having a two-layer structure composed of an AlN single crystal as a whole, which is distinguishable into a first layer and a second layer in a thickness direction based on an impurity concentration,
wherein the AlN single-crystal substrate comprises boron as an impurity,
wherein a boron atom concentration in the first layer is 9.4×10¹⁸ cm⁻³ or more, and
wherein the boron atom concentration in the first layer is at least 10 times a boron atom concentration in the second layer.

### Aspect 2

The AlN single-crystal substrate according to aspect 1, wherein a carbon atom concentration in the second layer is at least 10 times a carbon atom concentration in the first layer.

### Aspect 3

The AlN single-crystal substrate according to aspect 1 or 2, wherein an oxygen atom concentration in the second layer is at least twice an oxygen atom concentration in the first layer.

### Aspect 4

The AlN single-crystal substrate according to any one of aspects 1 to 3, wherein the boron atom concentration in the first layer is 9.4×10¹⁸ to 8.6×10¹⁹ cm⁻³ and the boron atom concentration in the second layer is less than 7.0×10¹⁷ cm⁻³.

### Aspect 5

The AlN single-crystal substrate according to any one of aspects 1 to 4, wherein the carbon atom concentration in the first layer is 1.0×10¹⁸ to 5.0×10¹⁹ cm⁻³ and the carbon atom concentration in the second layer is 1.0×10¹⁹ to 5.0×10²⁰ cm⁻³.

### Aspect 6

The AlN single-crystal substrate according to any one of aspects 1 to 5, wherein the oxygen atom concentration in the first layer is 1.0×10¹⁸ to 7.0×10¹⁹ cm⁻³ and the oxygen atom concentration in the second layer is 1.0×10¹⁹ to 8.0×10²⁰ cm⁻³.

### Aspect 7

The AlN single-crystal substrate according to any one of aspects 1 to 6, wherein the AlN single-crystal substrate has an area of 75 to 18500 mm² and a thickness of 0.10 to 1.00 mm.

### Aspect 8

The AlN single-crystal substrate according to any one of aspects 1 to 7, wherein the second layer is thicker than the first layer.

### Aspect 9

The AlN single-crystal substrate according to any one of aspects 1 to 8, wherein the surface of the first layer is Al-polar surface, and the surface of the second layer is N-polar surface.

### Aspect 10

A device comprising the AlN single-crystal substrate according to any one of aspects 1 to 9.

### BRIEF DESCRIPTION OF THE DRAWINGS

FIG. 1 is a schematic cross-sectional view showing an example of the structure of a heat treatment apparatus used to prepare AlN raw material powder.

FIG. 2 is a schematic cross-sectional view showing an example of the structure of a heat treatment apparatus used to prepare AlN raw material powder.

FIG. 3 is a schematic cross-sectional view showing the structure of a film forming apparatus used for a sublimation method.

### DETAILED DESCRIPTION OF THE INVENTION

### AlN Single-Crystal Substrate

The AlN single-crystal substrate of the present invention has a two-layer structure composed of an AlN single crystal as a whole, which is distinguishable into a first layer and a second layer in a thickness direction based on an impurity concentration. The AlN single-crystal substrate comprises boron as an impurity. In this case, the boron atom concentration in the first layer is 9.4×10¹⁸ cm⁻³ or more. The boron atom concentration in the first layer is at least 10 times the boron atom concentration in the second layer. By forming an AlN single-crystal substrate having a two-layer structure composed of an AlN single crystal as a whole with a controlled concentration of boron atoms as impurities as described above, chipping is less likely to occur when the AlN single-crystal substrate is processed (such as ground, polished, or cut). Therefore, by subjecting such an AlN single-crystal substrate to processing, the AlN single-crystal substrate can be manufactured at a high yield. In other words, as described above, conventional AlN single-crystal substrates are susceptible to chipping when processed (such as ground, polished, or cut), leaving room for improvement in terms of yield. The AlN single-crystal substrate of the present invention can advantageously solve this problem.

Here, “the AlN single-crystal substrate having a two-layer structure composed of an AlN single crystal as a whole, which is distinguishable into a first layer and a second layer in a thickness direction based on an impurity concentration” refers to an AlN single-crystal substrate which can be conveniently or conceptually distinguished into two layers, a first layer and a second layer (also referred to, when appropriate, as a first region and a second region of the two layered regions) based on the impurity concentrations measured by known methods, although it is difficult to recognize the two-layer structure through cross-sectional observation due to the single-crystal nature of the substrate. The term also refers to an AlN single-crystal substrate that, while being distinguishable into two layers based on differences in impurity concentration, has no grain boundaries between the layers and is identified as a single crystal as a whole. Here, the AlN single-crystal substrate is distinguishable into two layers based on differences in impurity concentration by the following measurement. For example, the first and second layers can be distinguished by measuring the impurity concentration in the thickness direction of the AlN single-crystal substrate by dynamic secondary ion mass spectrometry (D-SIMS) or the like. Specifically, the impurity concentration on the surface of the AlN single-crystal substrate is first measured; the substrate is then polished in increments of a predetermined thickness (e.g., 1/10 of the total thickness of the substrate, or 30 μm), and the impurity concentration of each surface exposed by polishing is measured; and by repeating this process, the distribution of impurity concentration in the thickness direction is obtained. Then, the plane having the highest impurity concentration in the AlN single-crystal substrate is identified. Next, the region where the impurity concentration is less than one-tenth of the highest impurity concentration is defined as the second layer, and the boundary between the first and second layers is identified. In this manner, the first and second layers of the AlN single-crystal substrate can be distinguished from each other. Here, the average of the impurity concentrations measured in the first layer region is used as the impurity concentration in the first layer, and the average of the impurity concentrations measured in the second layer region is used as the impurity concentration in the second layer. Preferably, the boron atom concentration is measured as the impurity concentration for distinguishing the first and second layers.

The area and thickness of the AlN single-crystal substrate are not particularly limited as long as an AlN single-crystal substrate having a two-layer structure composed of an AlN single crystal as a whole with a controlled concentration of boron atoms as impurities is obtained. Thus, the area of the AlN single-crystal substrate is typically 75 to 18500 mm² and the thickness of the AlN single-crystal substrate is typically 0.10 to 1.00 mm.

The AlN single-crystal substrate includes boron as impurities, and the boron atom concentration in the first layer is 9.4×10¹⁸ cm⁻³ or more, preferably 9.4×10¹⁸ to 8.6×10¹⁹ cm⁻³, more preferably 9.7×10¹⁸ to 6.0×10¹⁹ cm⁻³, and further preferably 1.0×10¹⁹ to 4.5×10¹⁹ cm⁻³. On the other hand, the boron atom concentration in the second layer is preferably less than 7.0×10¹⁷ cm⁻³. As described above, since the boron content as an impurity is higher in the first layer than in the second layer, an AlN single-crystal substrate that is less susceptible to chipping during processing can be obtained. Therefore, it is preferable that the boron atom concentration in the first layer is 9.4×10¹⁸ to 8.6×10¹⁹ cm⁻³, and the boron atom concentration in the second layer is less than 7.0×10¹⁷ cm⁻³. In this point of view, the boron atom concentration in the first layer is at least 10 times, preferably 13 to 100 times, more preferably 20 to 80 times, and further preferably 30 to 60 times the boron atom concentration in the second layer.

It is preferable that the AlN single-crystal substrate includes carbon as an impurity. In that case, the carbon atom concentration in the first layer is preferably 1.0×10¹⁸ to 5.0×10¹⁹ cm⁻³, more preferably 3.0×10¹⁸ to 3.0×10¹⁹ cm⁻³, and further preferably 5.0×10¹⁸ to 1.0×10¹⁹ cm⁻³. On the other hand, the carbon atom concentration in the second layer is preferably 1.0×10¹⁹ to 5.0×10²⁰ cm⁻³, more preferably 5.0×10¹⁹ to 2.0×10²⁰ cm⁻³, and further preferably 7.0×10¹⁹ to 1.0×10²⁰ cm⁻³. Since the carbon atom concentrations in both the first and second layers fall within the above-mentioned range, an AlN single-crystal substrate less susceptible to chipping during processing can be obtained. Therefore, it is preferable that the carbon atom concentration in the first layer is 1.0×10¹⁸ to 5.0×10¹⁹ cm⁻³, and the carbon atom concentration in the second layer is 1.0×10¹⁹ to 5.0×10²⁰ cm⁻³.

Furthermore, while the boron content is higher in the first layer than in the second layer, the carbon content is preferably higher in the second layer than in the first layer, thereby providing an AlN single-crystal substrate that is less susceptible to chipping during processing. In this point of view, the carbon atom concentration in the second layer is preferably at least 10 times, more preferably 11 to 40 times, and further preferably 12 to 30 times the carbon atom concentration in the first layer.

It is preferable that the AlN single-crystal substrate includes oxygen as an impurity. In that case, the oxygen atom concentration in the first layer is preferably 1.0×10¹⁸ to 7.0×10¹⁹ cm⁻³, more preferably 4.0×10¹⁸ to 5.0×10¹⁹ cm⁻³, and further preferably 9.0×10¹⁸ to 3.0×10¹⁹ cm⁻³. On the other hand, the oxygen atom concentration in the second layer is preferably 1.0×10¹⁹ to 8.0×10²⁰ cm⁻³, more preferably 1.5×10¹⁹ to 4.0×10²⁰ cm⁻³, and further preferably 1.9×10¹⁹ to 1.0×10²⁰ cm⁻³. Since the oxygen atom concentrations in both the first and second layers fall within the above-mentioned range, an AlN single-crystal substrate less susceptible to chipping during processing can be obtained. Therefore, it is preferable that the oxygen atom concentration in the first layer is 1.0×10¹⁸ to 7.0×10¹⁹ cm⁻³, and the oxygen atom concentration in the second layer is 1.0×10¹⁹ to 8.0×10²⁰ cm⁻³.

Furthermore, while the boron content is higher in the first layer than in the second layer, the oxygen content is preferably higher in the second layer than in the first layer, thereby providing an AlN single-crystal substrate that is less susceptible to chipping during processing. In this point of view, the oxygen atom concentration in the second layer is preferably at least 2 times, more preferably 3 to 20 times, and further preferably 4 to 10 times the oxygen atom concentration in the first layer.

As described above, controlling the impurity concentrations of the first and second layers that form the AlN single-crystal substrate makes it possible to obtain an AlN single-crystal substrate that is less susceptible to chipping during processing. The thickness of each of the first and second layers is not particularly limited, but the second layer is preferably thicker than the first. It is preferable that the top surface (the surface of the first layer) of the AlN single-crystal substrate is Al-polar surface, and the bottom surface (the surface of the second layer) is N-polar surface.

The first and second layers forming the AlN single-crystal substrate are AlN single-crystals, and can also be regarded as oriented layers. In the present invention, the term AlN single crystal refers to a crystal oriented in both the c-axis and a-axis directions and includes mosaic crystals. The mosaic crystal refers to a crystal that does not have distinct grain boundaries but is an aggregation of crystals whose crystal orientation slightly deviates from one or both of the c- and a-axes. Such an oriented layer has a structure in which the crystal orientation is substantially aligned with a substantially normal direction (c-axis direction) and an in-plane direction (a-axis direction). Such a structure allows a semiconductor layer with an excellent quality, particularly an excellent orientation, to be formed on the oriented layer. That is, when forming a semiconductor layer on the oriented layer, the crystal orientation of the semiconductor layer substantially matches the crystal orientation of the oriented layer. Thus, an oriented semiconductor film can be formed on the AlN single-crystal substrate.

In the first and second layers, AlN crystal is oriented in both the c-axis and a-axis directions. Methods of evaluating the orientation include, but are not specifically limited to, known analytical techniques such as the EBSD (Electron Back Scatter Diffraction Patterns) method and X-ray pole figures. For example, when using the EBSD method, an inverse pole figure map and a crystal orientation map of a surface (plate surface) or a cross section orthogonal to the plate surface of the AlN single-crystal layer are measured. The AlN single-crystal layer can be defined as being oriented along the two axes in the substantially normal direction and a substantially plate-surface direction, when the following conditions are satisfied: in the obtained inverse pole figure map, (A) the crystals are oriented in a specific orientation (first axis) in the substantially normal direction with respect to the plate surface, and (B) the crystals are oriented in a specific orientation (second axis) in the substantially in-plane plate-surface direction, orthogonal to the first axis; and in the obtained crystal orientation map, (C) the inclination angle from the first axis is distributed within ±10°, and (D) the inclination angle from the second axis is distributed within ±10°. In other words, when the above-described four conditions are satisfied, the AlN single-crystal layer can be determined as being oriented along the two axes, i.e., the c- and a-axes. For example, when the substantially normal direction with respect to the plate surface is oriented along the c-axis, the substantially in-plane plate-surface direction may be oriented in a specific orientation (for example, the a-axis) orthogonal to the c-axis. While the AlN single-crystal may be oriented along the two axes in the substantially normal direction and the substantially in-plane plate-surface direction, it is preferred that the substantially normal direction is oriented along the c-axis. The smaller the inclination angle distribution in the substantially normal direction and/or the substantially in-plane plate-surface direction, the smaller the mosaicity of the AlN single-crystal; and the closer the inclination angle distribution is to zero, the closer the AlN single-crystal is to a perfect single crystal. Therefore, from the viewpoint of crystallinity of the AlN single-crystal, the inclination angle distribution is preferably smaller in both the substantially normal direction and the substantially plate-surface direction, and is preferably within +5° or less, and more preferably within +3° or less, for example.

### Method of Manufacture

The AlN single-crystal substrate of the present invention may be produced by various methods as long as the boron atom concentration in the first layer is 9.4×10¹⁸ cm⁻³ or more; the boron atom concentration in the first layer is at least 10 times the boron atom concentration in the second layer; and a substrate having a two-layer structure composed of an AlN single crystal as a whole can be obtained. A seed substrate may be provided and then an epitaxial film may be formed thereon, or the AlN single-crystal substrate may be directly manufactured by spontaneous nucleation without using a seed substrate. The seed substrate to be used may be an AlN substrate to achieve homoepitaxial growth, or may be a substrate other than the AlN substrate to achieve heteroepitaxial growth. While any of a vapor phase deposition method, a liquid phase deposition method, and a solid phase deposition method may be used to grow a single crystal, the vapor phase deposition method is preferably used to form an AlN single crystal, and then the seed substrate portion is ground away, as required, to obtain a desired AlN single-crystal substrate. Examples of the vapor phase deposition method include various CVD (chemical vapor deposition) methods (such as thermal CVD, plasma CVD, and MOVPE), a sputtering method, hydride vapor phase epitaxy (HVPE), molecular beam epitaxy (MBE), a sublimation method, and pulsed laser deposition (PLD), with the sublimation method or HVPE being preferred. Examples of the liquid phase deposition method include solution growth methods (such as a flux method). Alternatively, the AlN single-crystal substrate can be obtained without directly forming an AlN single crystal on a seed substrate, by the steps of forming an unoriented precursor layer, forming the unoriented precursor layer into an AlN single-crystal layer by heat treatment, and grinding the seed substrate away. Examples of methods of forming the unoriented precursor layer in this case include an aerosol deposition (AD) method and a hypersonic plasma particle deposition (HPPD) method.

While any of the solid phase deposition method, vapor phase deposition method, and liquid phase deposition method described above may employ known conditions, a technique of fabricating the AlN single-crystal substrate using the sublimation method, for example, is hereinafter described. Specifically, the AlN single-crystal substrate is fabricated by (a) preparing an AlN raw material powder for the second layer, (b) preparing an AlN raw material powder for the first layer, (c) forming an AlN single-crystal layer and (d) grinding a seed substrate away and polishing the surface of the AlN single-crystal layer.

### (a) Preparation of AlN Raw Material Powder for Second Layer

This step is the step of heat-treating polycrystalline AlN powder to obtain AlN raw material powder for forming the second layer. As shown in FIG. 1, AlN powder 12 is placed as an AlN single-crystal raw material in a sheath 10 and heat-treated in a N₂ atmosphere. At this stage, a crucible 16 containing graphite powder 14 is placed in the sheath 10, avoiding direct contact with the AlN powder 12. The crucibles 16 have a size to be accommodated in the sheath 10. The pressure in the furnace in the sheath 10 is preferably 0.1 to 10 atmospheres, and more preferably 0.5 to 5 atmospheres. The heat-treatment temperature is preferably 1900 to 2300° C., and more preferably 2000 to 2200° C. Preferred examples of materials forming the sheath and the crucibles include tantalum carbide, tungsten, molybdenum, and carbon, with carbon being preferred.

### (b) Preparation of AlN Raw Material Powder for First Layer

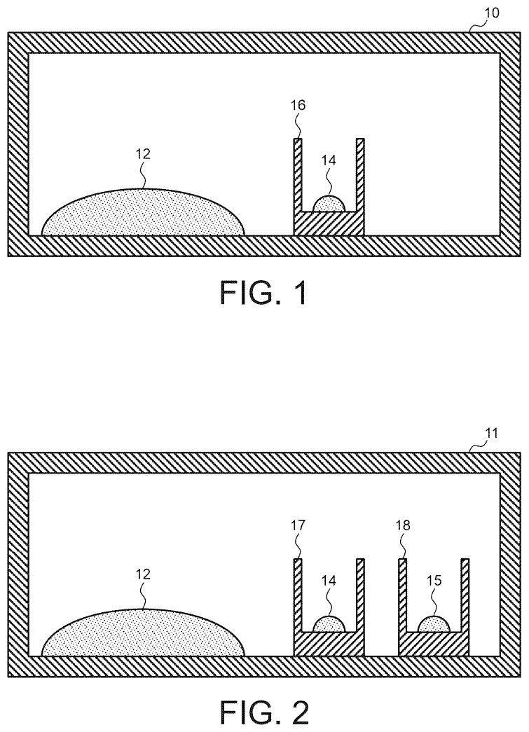

This step is the step of heat-treating polycrystalline AlN powder to obtain AlN raw material powder for forming the first layer. As shown in FIG. 2, AlN powder 12 is placed as an AlN single-crystal raw material in a sheath 11 and heat-treated in a N₂ atmosphere. At this stage, a crucible 17 containing graphite powder 14 and a crucible 18 containing boron nitride (BN) powder 15 are placed in the sheath 11, avoiding direct contact with the AlN powder 12. At this point, by adjusting the content of the BN powder 15 relative to 100 parts by weight of the AlN powder, the impurity concentration in the first layer constituting the AlN single-crystal substrate finally obtained can be controlled. The crucibles 17 and 18 have a size to be accommodated in the sheath 11. The pressure in the furnace in the sheath 11 is preferably 0.1 to 10 atmospheres, and more preferably 0.5 to 5 atmospheres. The heat-treatment temperature is preferably 1900° C. to 2300° C., and more preferably 2000 to 2200° C. Preferred examples of materials forming the sheath and the crucibles include tantalum carbide, tungsten, molybdenum, and boron nitride (BN), with BN being preferred.

### (c) Forming AlN Single-Crystal Layer

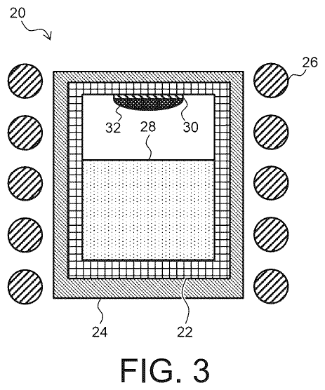

This step is the step of forming an AlN single crystal on a seed substrate in a crystal growth apparatus. FIG. 3 shows one example of the crystal growth apparatus used in the sublimation method. A film formation apparatus 20 shown in FIG. 3 includes a crucible 22, a heat insulating material 24 for heat-insulating the crucible 22, and coils 26 for heating the crucible 22 to a high temperature. The crucible 22 contains AlN raw material powder 28 at a lower portion thereof and has a seed substrate 30 at an upper portion thereof, on which sublimated AlN raw material powder 28 is to be deposited. The crucible 22 is pressurized in an N₂ atmosphere, and the crucible 22 is heated with the coils 26 to sublimate the AlN raw material powder 28. The pressure is preferably 10 to 100 kPa, and more preferably 20 to 90 kPa. Here, a temperature gradient is generated such that the temperature near the seed substrate 30 at the upper portion of the crucible 22 is lower than the temperature near the AlN raw material powder 28 at the lower portion of the crucible 22. For example, a portion of the crucible 22 near the AlN raw material powder 28 is preferably heated to 1900 to 2250° C., and more preferably 2000 to 2200° C.; and a portion of the crucible 22 near the seed substrate 30 is preferably heated to 1400 to 2150° C., and more preferably 1500 to 2050° C. Here, the temperature of the portion near the seed substrate 30 is preferably lower by 100 to 500° C., more preferably 200 to 400° C., than the temperature near the AlN raw material powder 28. Such heating is preferably maintained for 2 to 100 hours, and more preferably 4 to 90 hours. The temperature can be controlled by measuring temperatures at the upper and lower portions of the crucible 22 with a radiation thermometer (not shown) through holes in the heat insulating material 24 covering the crucible 22, and feeding the results back to the temperature adjustment. In this manner, a SiC single crystal is placed as the seed substrate 30, for example, and AlN is re-deposited on the surface of the seed substrate 30 to allow an AlN single-crystal layer 32 to be formed.

### (d) Grinding Seed Substrate Away and Polishing Surface of AlN Single-Crystal Layer

This step includes the grinding step of grinding the seed substrate away to expose the AlN single-crystal layer; and the polishing step of removing irregularities and defects on the surface of the AlN single crystal. The SiC single crystal remains on the AlN single-crystal layer fabricated by the steps (a) to (c) above using the SiC substrate as the seed substrate, and thus, the seed substrate is subjected to grinding to expose the surface of the AlN single-crystal layer. Additionally, to mirror-finish the surface of the formed AlN single-crystal layer, the plate surface is smoothed by lapping with diamond abrasive grains and then polished by chemical mechanical polishing (CMP) with colloidal silica or the like. In this manner, the AlN single-crystal substrate can be fabricated.

### Device

A device can also be fabricated using the AlN single-crystal substrate of the present invention. That is, preferably, a device comprising the AlN single-crystal substrate is provided. Examples of such devices include deep ultraviolet laser diodes, deep ultraviolet diodes, power electronic devices, high-frequency devices, and heat sinks. Methods for manufacturing the device using the AlN single-crystal substrate are not specifically limited, and known techniques may be employed to manufacture the device.

### EXAMPLES

The present invention is described in more detail with the following examples.

### Examples 1 to 9

### (1) Fabrication of AlN Single-Crystal Substrates

### (1a) Preparation of AlN Raw Material Powder for Second Layer

The structure of the heat treatment apparatus used to prepare AlN raw material powder is shown in FIG. 1. As shown in FIG. 1, commercially available AlN powder 12 with an average particle diameter of 1 μm used as the AlN single crystal raw material was placed in the carbon sheath 10. Commercially available graphite powder 14 with an average particle diameter of 1 μm was added to a carbon crucible 16 in a proportion of 6 parts by weight relative to 100 parts by weight of the AlN powder. The carbon crucible 16 was placed in the carbon sheath 10, avoiding direct contact with the AlN powder 12. The carbon crucible 16 has a size to be accommodated in the sheath 10. The carbon sheath 10 was heat-treated in a graphite heater furnace at 2200° C. under 0.1 to 10 atmospheres in a N₂ atmosphere. In this manner, the polycrystalline AlN powder 12 was heat-treated to prepare the AlN raw material powder for forming the second layer.

### (1b) Preparation of AlN Raw Material Powder for First Layer

The structure of the heat treatment apparatus used to prepare AlN raw material powder is shown in FIG. 2. As shown in FIG. 2, commercially available AlN powder 12 with an average particle diameter of 1 μm used as the AlN single-crystal raw material was placed in the BN sheath 11. Commercially available graphite powder 14 with an average particle diameter of 1 μm was added to a BN crucible 17 in a proportion of 6 parts by weight relative to 100 parts by weight of the AlN powder. The BN crucible 17 was placed in the BN sheath 11, avoiding direct contact with the AlN powder 12. Furthermore, a BN crucible 18 containing BN powder 15 with an average diameter of 3 μm was placed in the BN sheath 11, avoiding direct contact with the AlN powder 12. At this point, in Example 1, the BN powder 15 was added to the BN crucible 18 in a proportion of 3 parts by weight relative to 100 parts by weight of the AlN powder. In Examples 2 to 9, the content of the BN powder 15 relative to 100 parts by weight of the AlN powder was adjusted so that the impurity concentration in the first layer constituting the AlN single-crystal substrate finally obtained was as shown in Table 1. The BN crucibles 17 and 18 have a size to be accommodated in the BN sheath 11. The BN sheath 11 was heat-treated in a graphite heater furnace at 2200° C. under 0.1 to 10 atmospheres in a N₂ atmosphere. In this manner, the polycrystalline AlN powder 12 was heat-treated to prepare the AlN raw material powder for forming the first layer.

### (1c) Formation of AlN Single-Crystal Layer

The structure of the film forming apparatus used for the sublimation method is shown in FIG. 3. The film forming apparatus 20 includes a heat insulating material 24 for heat-insulating the crucible 22, a crystal growth container, and coils 26 for heating the crucible 22. As shown in FIG. 3, the crucible 22 containing the AlN raw material powder 28 for forming the second layer prepared in (1a) above was placed in the film forming apparatus 20. Furthermore, a SiC substrate serving as a seed substrate 30, on which a sublimate of the AlN raw material powder 28 was deposited, was placed at the upper part of the crucible 22, avoiding direct contact with the AlN raw material powder 28. Next, the crucible 22 was pressurized to 50 kPa under a N₂ atmosphere, and the area around the AlN raw material powder 28 in the crucible 22 was heated to 2100° C. by high-frequency induction heating using the coil 26. On the other hand, the area around the SiC substrate in the crucible 22 was heated and maintained at a temperature lower than that (temperature difference: 200° C.), thereby redepositing the AlN single-crystal layer 32 (the second layer) on the SiC substrate. The retention time was 10 hours. Subsequently, using, as a seed substrate 30, the second layer formed on the SiC substrate, and the AlN raw material powder 28 for forming the first layer, an AlN single-crystal layer 32 (the first layer) was redeposited on the second layer in the same manner as described above.

### (1d) Grinding SiC Substrate Away and Polishing Surface of AlN Single-Crystal Layer

The SiC substrate having AlN re-deposited thereon, obtained in (1c) above, was ground using a grinding wheel of a size up to #2000, until the AlN single crystal was exposed, and the plate surface was further smoothed by lapping with diamond abrasive grains. Then, the plate surface was subjected to chemical mechanical polishing (CMP) with colloidal silica to be mirror-finished. Thus, a circular AlN single-crystal substrate having the area and thickness as shown in FIG. 2 and having a two-layer structure composed of an AlN single crystal as a whole, which is distinguishable into a first layer and a second layer in a thickness direction based on an impurity concentration was prepared.

### (2) Evaluation of AlN Single-Crystal Substrate

### (2a) EBSD Measurement

Top and bottom surfaces of the AlN single-crystal substrate were subjected to EBSD measurement. The results showed that the AlN crystals were oriented in both the c- and a-axis directions.

(2b) Concentration of Each Atom within AlN Single-Crystal Substrate

The polished surface of the AlN single-crystal substrate was subjected to dynamic secondary ion mass spectrometry (D-SIMS). The measurement was performed using IMS-7f manufactured by CAMECA as the analytical apparatus, under the following conditions: primary ion species: Cs⁺, primary acceleration voltage: 15 kv, and detection range: 25 μm×25 μm. This measurement was performed at 10 measurement points on the polished surface of the AlN single-crystal substrate. These 10 measurement points were defined on the circular substrate surface, as follows: (i) 10 straight lines were drawn radially from the center of the substrate to the outer circumference, so as to divide the circular shape of the substrate into 10 equal parts (i.e., so that adjacent straight lines formed an angle of 36 degrees), and (ii) positions where the distance from the center of the substrate on each of these 10 straight lines is 50% of the radius of the substrate were defined as the measurement points.

In Examples 1 to 7, the average boron atom concentration at a depth of 1 to 3 μm from the substrate surface (the top surface) in the first layer region was measured at each measurement point, and the boron atom concentration in the first layer (cm⁻³) was determined by calculating the average over 10 measurement points. The carbon atom concentration (cm⁻³) and the oxygen atom concentration (cm⁻³) in the first layer were determined in the same manner as described above. Furthermore, the boron atom concentration, the carbon atom concentration, and the oxygen atom concentration at a depth of 1 to 3 μm from the substrate surface (the bottom surface) in the second layer region were determined at each measurement point in the same manner as described above. Thus, the boron atom concentration (cm⁻³), the carbon atom concentration (cm⁻³), and the oxygen atom concentration (cm⁻³) in the first and second layers were determined. Moreover, the ratio of the boron atom concentration in the first layer to the boron atom concentration in the second layer, the ratio of the carbon atom concentration in the second layer to the carbon atom concentration in the first layer, and the ratio of the oxygen atom concentration in the second layer to the oxygen atom concentration in the first layer were determined. The results are shown in Table 1.

The regions of the first layer and the second layer in the AlN single-crystal substrate were identified as described below. Specifically, the boron atom concentration of the AlN single-crystal substrate was measured at depths in 30 μm increments from the surface in the thickness direction, and the plane inside the AlN single-crystal substrate with the highest boron atom concentration was identified. The region where the boron atom concentration is less than one-tenth of the highest boron atom concentration was defined as the second layer, and the remainder was defined as the first layer.

In contrast, the aforementioned first and second layers could not be identified in Examples 8 and 9. Thus, the concentration of each atom was measured at the aforementioned 10 measurement points on the top surface of the AlN single-crystal substrate, and the averages over the 10 points were determined as the boron atom concentration, the carbon atom concentration, and the oxygen atom concentration in the first layer. Furthermore, the concentration of each atom was measured at the aforementioned 10 measurement points on the bottom surface of the AlN single-crystal substrate, and the averages over the 10 points were determined as the boron atom concentration, the carbon atom concentration, and the oxygen atom concentration in the second layer. In this measurement, the lower detection limit of the boron atom concentration is 7.0×10¹⁷ cm⁻³, the lower detection limit of the carbon atom concentration is 1.0×10¹⁶ cm⁻³, and the lower detection limit of the oxygen atom concentration is 5.0×10¹⁷ cm⁻³. The results are shown in Table 1.

The first and second layers in Examples 1 to 7 were identified using the aforementioned method, and their thicknesses were measured, revealing that the second layer was thicker than the first.

### (2c) Examination of Chipping

The surface of the AlN single-crystal substrate after grinding and polishing in (1d) above was observed with an optical microscope to examine for chipping with a maximum length of 50 μm or more. A total of 10 AlN single-crystal substrates were fabricated using the same method as described in (1) above, and it was examined how many of these AlN single-crystal substrates had chipping, and then the AlN single-crystal substrates were rated according to the evaluation criteria shown below. The results are shown in Table 2.

### <Evaluation Criteria>

Rating A: Nine or ten AlN single-crystal substrates were free of chipping
Rating B: Six to eight AlN single-crystal substrates were free of chipping
Rating C: Three to five AlN single-crystal substrates were free of chipping
Rating D: All of the AlN single-crystal substrates showed chipping

### (2d) Examination of Polarity

The polarity was examined by performing chemical mechanical polishing (CMP) on the surface of the AlN single-crystal substrate after grinding and polishing in (1d) above. The polishing rate is low when the surface is Al-polar surface, and high when it is N-polar surface. This confirmed that the top surface (i.e., the surface of the first layer) of the AlN single-crystal substrate is Al-polar surface, and that the bottom surface (i.e., the surface of the second layer) is N-polar surface.

TABLE 1

| | B atom concentration | | | C atom concentration | | | O atom concentration | | |
|---|---|---|---|---|---|---|---|---|---|
| | | | B atom | | | C atom | | | O atom |
| | | | concentration | | | concentration | | | concentration |
| | | | in first | | | in second | | | in second |
| | First | Second | layer/B atom | First | Second | layer/C atom | First | Second | layer/O atom |
| | layer | layer | concentration | layer | layer | concentration | layer | layer | concentration |
| | (cm⁻³) | (cm⁻³) | in second layer | (cm⁻³) | (cm⁻³) | in first layer | (cm⁻³) | (cm⁻³) | in first layer |
| Example 1 | 2.2 × 10¹⁹ | <7.0 × 10¹⁷ | >31 | 6.6 × 10¹⁸ | 7.7 × 10¹⁹ | 12 | 2.0 × 10¹⁹ | 8.9 × 10¹⁹ | 4 |
| Example 2 | 1.2 × 10¹⁹ | <7.0 × 10¹⁷ | >17 | 8.0 × 10¹⁸ | 7.7 × 10¹⁹ | 10 | 1.2 × 10¹⁹ | 8.9 × 10¹⁹ | 7 |
| Example 3 | 9.6 × 10¹⁸ | <7.0 × 10¹⁷ | >14 | 9.0 × 10¹⁸ | 1.3 × 10²⁰ | 14 | 8.0 × 10¹⁸ | 1.5 × 10²⁰ | 19 |
| Example 4 | 2.2 × 10¹⁹ | <7.0 × 10¹⁷ | >31 | 6.6 × 10¹⁸ | 7.7 × 10¹⁹ | 12 | 2.0 × 10¹⁹ | 8.9 × 10¹⁹ | 4 |
| Example 5 | 2.2 × 10¹⁹ | <7.0 × 10¹⁷ | >31 | 6.6 × 10¹⁸ | 7.7 × 10¹⁹ | 12 | 2.0 × 10¹⁹ | 8.9 × 10¹⁹ | 4 |
| Example 6 | 2.2 × 10¹⁹ | <7.0 × 10¹⁷ | >31 | 6.6 × 10¹⁸ | 7.7 × 10¹⁹ | 12 | 2.0 × 10¹⁹ | 8.9 × 10¹⁹ | 4 |
| Example 7 | 4.0 × 10¹⁹ | <7.0 × 10¹⁷ | >57 | 4.0 × 10¹⁸ | 1.3 × 10²⁰ | 33 | 4.0 × 10¹⁹ | 1.5 × 10²⁰ | 4 |
| Example 8* | <7.0 × 10¹⁷ | <7.0 × 10¹⁷ | — | 1.5 × 10¹⁹ | 1.5 × 10¹⁹ | 1 | 4.3 × 10¹⁸ | 4.3 × 10¹⁸ | 1 |
| Example 9* | 6.0 × 10¹⁸ | <7.0 × 10¹⁷ | >9 | 1.5 × 10¹⁹ | 1.5 × 10¹⁹ | 1 | 4.3 × 10¹⁸ | 4.3 × 10¹⁸ | 1 |

*indicates a comparative example.

TABLE 2

| | Area | Thickness | |
|---|---|---|---|
| | (mm²) | (mm) | Evaluation of chipping |
| Example 1 | 2026 | 0.40 | A |
| Example 2 | 2026 | 0.40 | B |
| Example 3 | 2026 | 0.40 | C |
| Example 4 | 8103 | 0.40 | B |
| Example 5 | 79 | 0.40 | A |
| Example 6 | 2026 | 0.70 | B |
| Example 7 | 2026 | 0.40 | C |
| Example 8* | 2026 | 0.40 | D |
| Example 9* | 2026 | 0.40 | D |

*indicates a comparative example.

What is claimed is:

1. An AlN single-crystal substrate having a two-layer structure composed of an AlN single crystal as a whole, which is distinguishable into a first layer and a second layer in a thickness direction based on an impurity concentration,
wherein the AlN single-crystal substrate comprises boron as an impurity,
wherein a boron atom concentration in the first layer is 9.4×10¹⁸ cm⁻³ or more, and
wherein the boron atom concentration in the first layer is at least 10 times a boron atom concentration in the second layer.

2. The AlN single-crystal substrate according to claim 1, wherein a carbon atom concentration in the second layer is at least 10 times a carbon atom concentration in the first layer.

3. The AlN single-crystal substrate according to claim 1, wherein an oxygen atom concentration in the second layer is at least twice an oxygen atom concentration in the first layer.

4. The AlN single-crystal substrate according to claim 1, wherein the boron atom concentration in the first layer is 9.4×10¹⁸ to 8.6×10¹⁹ cm⁻³ and the boron atom concentration in the second layer is less than 7.0×10¹⁷ cm⁻³.

5. The AlN single-crystal substrate according to claim 1, wherein the carbon atom concentration in the first layer is 1.0×10¹⁸ to 5.0×10¹⁹ cm⁻³ and the carbon atom concentration in the second layer is 1.0×10¹⁹ to 5.0×10²⁰ cm⁻³.

6. The AlN single-crystal substrate according to claim 1, wherein the oxygen atom concentration in the first layer is 1.0×10¹⁸ to 7.0×10¹⁹ cm⁻³ and the oxygen atom concentration in the second layer is 1.0×10¹⁹ to 8.0×10²⁰ cm⁻³.

7. The AlN single-crystal substrate according to claim 1, wherein the AlN single-crystal substrate has an area of 75 to 18500 mm² and a thickness of 0.10 to 1.00 mm.

8. The AlN single-crystal substrate according to claim 1, wherein the second layer is thicker than the first layer.

9. The AlN single-crystal substrate according to claim 1, wherein the surface of the first layer is Al-polar surface, and the surface of the second layer is N-polar surface.

10. A device comprising the AlN single-crystal substrate according to claim 1.
